(19) United States
(12) Patent Application Publication
(10) Pub. No.: US 2017/0141306 A1
(43) Pub. Date: May 18, 2017

(54) MEMORY STRUCTURE

(71) Applicant: CHANG GUNG UNIVERSITY, TAOYUAN CITY (TW)

(72) Inventors: SIDDHESWAR MAIKAP, TAOYUAN CITY (TW); DEBANJAN JANA, TAOYUAN CITY (TW)

(21) Appl. No.: 14/943,567

(22) Filed: Nov. 17, 2015

(51) Int. Cl. H01L 45/00

(52) U.S. Cl. CPC H01L 45/145; H01L 45/1253

(57) ABSTRACT

The present invention relates to a memory structure, which includes a dielectric layer between the top and bottom electrodes and further includes an iridium oxide film between the top electrode and the dielectric layer. With the iridium oxide film, the number of the metal particles in the electrodes diffusing to the dielectric layer in ion form or the number of oxygen vacancies in the memory can be controlled. Thereby, the operating voltage/current of the memory can be lowered and switching uniformity/reliability will be improved.

### FIELD OF THE INVENTION

The present invention relates to a memory structure, and particularly to memory structure having iridium oxide film.

### BACKGROUND OF THE INVENTION

Generally, memories can be classified into two types: volatile and non-volatile memories. The difference between the two is that the stored data in volatile memories disappear when the power breaks. Contrarily, the stored data will not disappear when the same condition occurs. After re-supplying the power, the stored data can be accessed.

Volatile memories are mainly categorized into dynamic random-access memories (DRAM) and static random-access memories (SRAM). The advantages of volatile memories include fast access time and low cost. On the other hand, the non-volatile memories according to the prior art can be categorized into read-only memories (ROM) and flash memories. The USB flash drives generally used are actually flash memories. The major technology therein is the NAND technology, which uses a floating-gate transistor to store data and differentiate between the “0” and “1” signals according to the number of electrons stored in the metal or oxide layer of semiconductor. lts drawbacks include high operating voltage, low speed, and deteriorated memory efficacy caused by thinning of the oxide layer by the tunneling effect during the process of device miniaturization.

Accordingly, in order to have the advantages of current memories while improving the problems of flash memories, scientists are devoted to developing novel non-volatile memories. Presently, novel non-volatile memories can be mainly classified into four types, including ferroelectric RAM (FERAM), magnetoresistive RAM (MRAM), phase-change RAM, and resistive RAM (RRAM).

Among the types, RRAM is the simplest memory in structure currently, including a layer of insulating layer sandwiched by two metal layers and forming a metal/insulator/metal (MIM) sandwich structure. Some researchers also propose a metal-insulator/semiconductor (MIS) structure. The “M” represents a good conductor. The top and bottom layers can be made of different materials. The “I” represents a dielectric material and is mainly composed by metal oxides.

The operation of RRAM is to apply a DC voltage across the device. Initially, the state of the device will be maintained at a low current. When the applied voltage reaches a threshold write voltage, the current will increase abruptly. At this moment, the device experiences resistance transformation. In other words, it changes from a low-current state to a high-current state. Meanwhile, in order to prevent damages on the device due to excess current, a current limit value will be set.

In order to switch the device back to the low-current state, the setting of the current limit value should be disabled first. When a voltage with the same polarity is applied again, the device will be kept in the high-current state until the voltage reaches a certain threshold erase voltage. Then the current value will decrease abruptly and the device will return to the original low-current state. Accordingly, the resistance value of the device is no longer a fixed value. Instead, the voltage-current characteristic of the device exhibits a nonlinear relation.

### SUMMARY

An objective of the present invention is to provide a memory structure, which can be used as a conductive-bridging RAM (CBRAM) in RRAM. An iridium oxide thin film is disposed below the top electrode for controlling the number of metal particles in the top electrode diffusing to the dielectric layer in ion form. Thereby, the operating voltage/current of the memory can be reduced and switching uniformity/reliability is improved by controlling the conducting filament diameter through iridium-oxide (IrOₓ) nano-net layer. The RRAM device can be named as I-RRAM, where ‘I’ stands for Ir nano-structure interfacial layer.

Another objective of the present invention is to provide a memory structure, which can be used as an RRAM. An iridium oxide thin film is disposed below the top electrode for controlling the number of oxygen vacancies in the memory and thus reducing the operating voltage/current of the memory as well as improved switching uniformity/reliability.

A further objective of the present invention is to provide a memory structure, which can determine the type of memory by selecting different metal material as the electrodes. Thereby, the application is extensive.

Accordingly, the present invention discloses a memory structure, which comprises a bottom electrode, a dielectric layer, an iridium oxide layer, and a top electrode. The dielectric layer is disposed on the bottom electrode. The iridium oxide film is disposed on the dielectric layer. The top electrode is disposed on the iridium oxide film.

### BRIEF DESCRIPTION OF THE DRAWINGS

FIG. 1 shows a structural schematic diagram of the memory structure according to a preferred embodiment of the present invention;

FIG. 2 shows a partial enlarged view of the memory structure according to a preferred embodiment of the present invention;

FIG. 3A shows a schematic diagram of the iridium oxide film, which is a thin film, according to a preferred embodiment of the present invention;

FIG. 3B shows a schematic diagram of the iridium oxide film, which is a thin film having a plurality of vacancies, according to a preferred embodiment of the present invention;

FIGS. 4A˜4D show real images of a preferred embodiment of the present invention; and

FIGS. 5A˜5D show analysis results of preferred embodiments of the present invention.

### DETAILED DESCRIPTION

In order to make the structure and characteristics as well as the effectiveness of the present invention to be further understood and recognized, the detailed description of the present invention is provided as follows along with embodiments and accompanying figures.

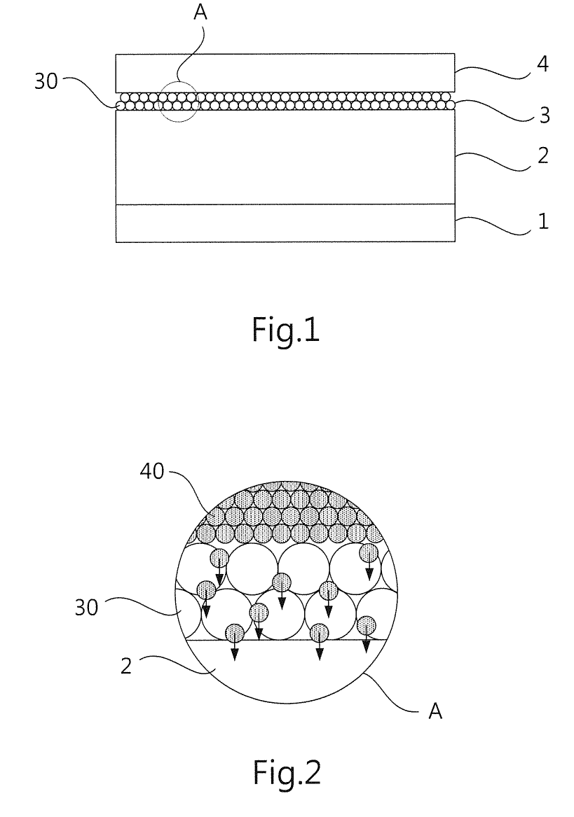

First, please refer to FIG. 1. According to a preferred embodiment of the present invention, the disclosed memory structure comprises a bottom electrode 1, a dielectric layer 2, an iridium oxide film 3, and a top electrode 4. The dielectric layer 2 is disposed on the bottom electrode 1. The iridium oxide film 3 is disposed on the dielectric layer 2. The top electrode 4 is disposed on the iridium oxide film 3.

The structure of an RRAM includes a metal/insulator/metal stack. By an applied bias voltage, the resistance value is altered for executing the write and erase operations. Then the device will be in a high- or low-resistance state corresponding to the “0” and “1” states in digital signals. The transition mechanism of a RRAM is achieved by conducting filament paths. When a bias voltage is applied to the RRAM, an oxygen vacancy conduction path can be formed in the dielectric layer by soft breakdown and transforming the RRAM to the low-resistance state. When the current passes through the filament paths, the high-power-density heat will be generated along the path partially and thus breaking the filament paths or oxygen vacancy will be migrated opposite direction. The device is thereby transformed to the high-impedance state. According to a preferred embodiment of the present invention, the top electrode is platinum, tungsten, titanium nitride or graphene, which will create oxygen vacancy to form the filament paths by applying a bias voltage.

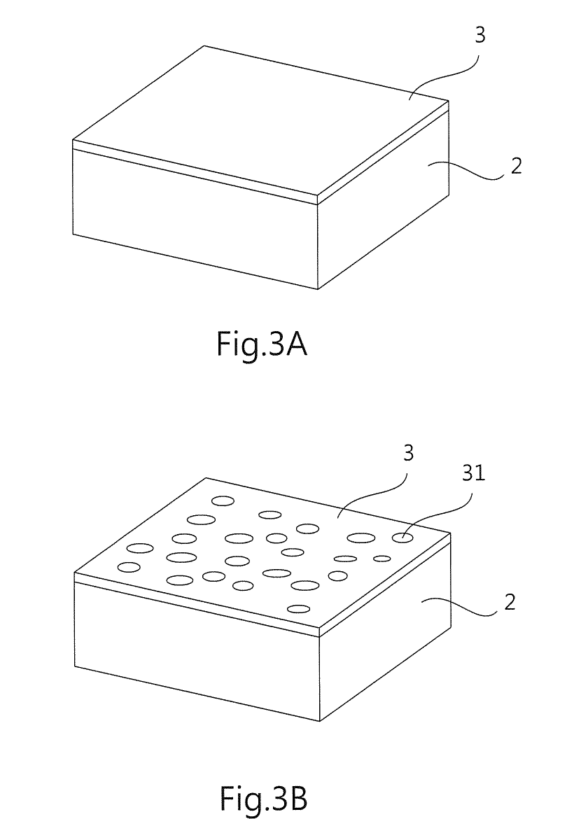

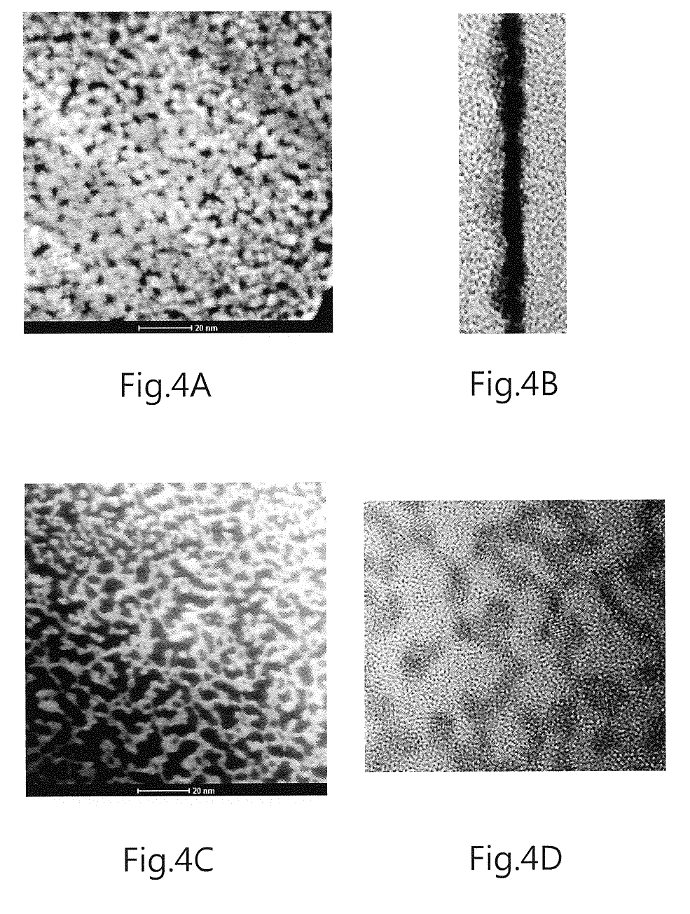

According to the above mechanism, the present invention can control the forming of the filament paths via the iridium oxide film 3 located between the top electrode 4 and the dielectric layer 2. According a preferred embodiment of the present invention, as referring to FIG. 2, the iridium oxide film 3 is formed by stacking a plurality of iridium oxide nano-structures 30. A plurality of metal particles 40 of the top electrode 4 pass through the iridium oxide film 3 via the gaps among the iridium oxide nano-structures 30 and contact the dielectric layer 2. More specifically, these metal particles 40 diffuse in the form of oxidized ions towards the direction of the dielectric layer 2. Thereby, when the iridium oxide nano-structures 30 are disposed on the dielectric layer 2 using the methods such as chemical vapor deposition (CVD), plasma-enhanced CVD (PECVD), vapor deposition, electron-gun vapor deposition, or radio-frequency (RF) sputtering, the difficulty of the metal particles 40 diffusing to the dielectric layer 2 can be altered by setting the thickness and distribution of the formed iridium oxide film 3. Furthermore, please refer to FIGS. 3A and 3B. The distribution of the iridium oxide film 3 on the dielectric layer 2 can be uniform and intact, as shown in FIG. 3A. Alternatively, the iridium oxide film 3 can be a thin film containing a plurality of vacancy parts 31, as shown in FIG. 3B. Overall, the thickness of the iridium oxide film 3 is 2 to 4 nanometers.

Through the usage of the iridium oxide film 3 and with the company of existing memory materials, namely, the top electrode 4 and the dielectric layer 2, so that the difficulty of the metal particles diffusion to the dielectric layer 2 can be altered. Essentially, the iridium oxide film 3 is used as the control factor for altering the operating voltage/current of the memory as well as uniformity/reliability. According to a preferred embodiment of the present invention, the iridium oxide film 3 can be used for reducing both the voltage and currents for forming and breaking the filament paths. Accordingly, the operating voltage/current of the memory can be lowered.

The material of the dielectric layer 2 is normally a binary metal oxide. According to a preferred embodiment of the present invention, the candidate materials include silicon oxide, aluminum oxide, tantalum oxide, hafnium oxide, zirconium oxide or gadolinium oxide. The material of the bottom electrode 1 is a normal material for metal electrodes, such as platinum, tungsten, and titenium nitride. In addition, graphene can be also used for scaling purpose.

In addition to forming the conduction paths by diffusing metal particles 40 in the oxidized-ion form, according to another preferred embodiment of the present invention, metal ions are used as the conduction mechanism, which is just an implementation of conductive bridging.

When a positive bias voltage is applied to a CBRAM, some damages will be generated on the electrode surfaces formed by metal reduced from the metal ions in the dielectric layer 2 and bursting out of the electrode surfaces. On the other hand, is a negative bias voltage is applied to the memory, the reduced metal ions of the dielectric layer 2 will be confined between the dielectric layer 2 and the top electrode 4. In other words, the metal ions of the dielectric layer 2 tend to move in different directions depending on the polarity of the bias voltage. Thereby, in practical operations, as the metal ions leave the dielectric layer 2, metal bridge will form. Then electrons will hop among the metal bridge and hence achieving conduction. Initial metal ions have been supplied from the top electrode by external positive bias on it.

According to the present preferred embodiment, the material of the top electrode 4 can be copper or silver. The material of the dielectric layer 2 can be silicon oxide, aluminum oxide, tantalum oxide, hafnium oxide, zirconium oxide or gadolinium oxide. The material of the bottom electrode 1 is normal materials for electrodes such as platinum, tungsten, titanium nitride, or graphene. Take the combination of titanium oxide and hafnium oxide, tantalum oxide, zirconium oxide or gadolinium oxide for example. Because the free energies of formation for titanium oxide (TiO₂) and hafnium oxide are close, TiOₓ and HfOₓ or TaOₓ will be formed at the interface between titanium oxide and hafnium oxide or tantalum oxide. This layer of TiOₓ can be regarded as the reservoir of oxygen. On the other hand, oxygen vacancy TaOₓ, HfOₓ, ZrOₓ, or GdOₓ, can be deposited by during different deposition methods. Furthermore, according to the present invention, although the iridium oxide film 3 is disposed between the dielectric layer 2 and the top electrode 4, since the iridium oxide film 3 is in the form of FIG. 3B, a portion of the dielectric layer 2 can still contact the top electrode 4.

Accordingly, when a reverse voltage is applied, the oxygen ions escape from the TiOₓ and fill into oxygen vacancies, leading to breakage of the filament paths formed by the oxygen vacancies originally. Then the resistance is transformed from the low-resistance state to the high-resistance state. As a positive bias voltage is applied, the filament paths formed by oxygen vacancies are formed again. That is to say, the filament paths formed by oxygen vacancies are connected and broken repeated, transforming between the high- and low-resistance states. According to the present preferred embodiment of the present invention, the iridium oxide film 3 is used for controlling the number of oxygen vacancies. By reducing the voltage required for forming and breaking the filament paths, the operating voltage of the memory can be lowered accordingly.

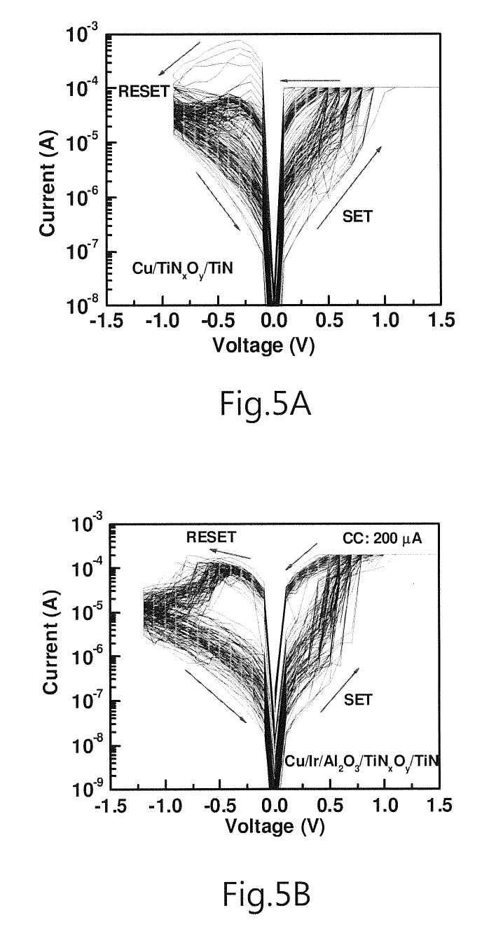

FIGS. 4A˜4C are real images of a preferred embodiment of the present invention. FIG. 4A is a plane-view transmission electron microscope (TEM) image shows porous IrOₓ nano-structure with a thickness of 5 nm on SiO₂/Si substrate. FIG. 4B is a cross-sectional TEM image of IrOₓ with a thickness of approximately 2 nm (the darker part). FIG. 4C is a plane-view TEM image shows nano-structure of IrOₓ with a thickness of 2 nm. FIG. 4D is a high-resolution TEM image shows inset of the nano-structure of IrOₓ. The IrOₓ₋nano-structure was deposited by RF sputtering.

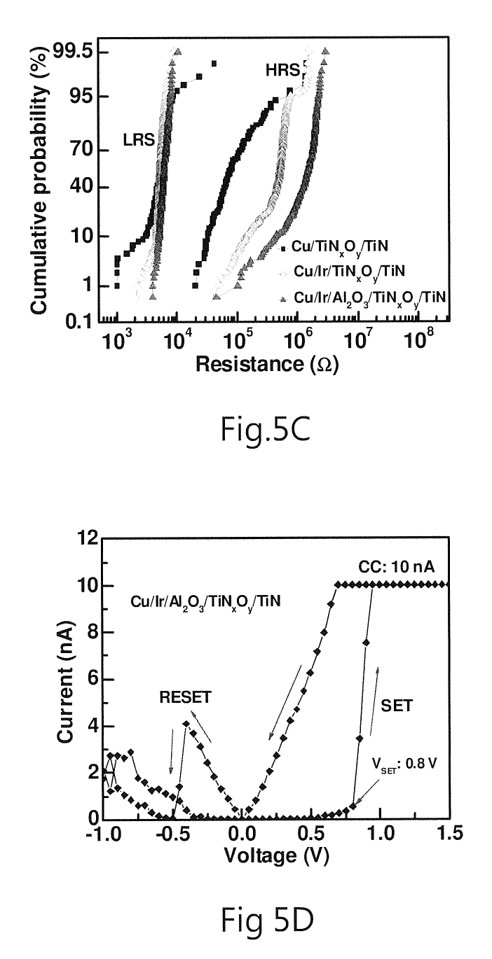

FIGS. 5A˜5D are some analysis results. FIGS. 5A shows a result of current-voltage characteristics without Ir nano-structure in a Cu/TiNₓO_{y}/TiN CBRAM device. FIG. 5B shows a result of current-voltage characteristics with Ir nano-structure in a Cu/Ir/Al₂O₃/TiNₓO_{y}/TiN CBRAM device. FIG. 5C shows the relationship between cumulative probability and resistance under different structures. FIG. 5D shows the current-voltage characteristics with Ir nano-structure in a Cu/Ir/Al₂O₃/TiNₓO_{y}/TiN I-RRAM device. The thicknesses of Ir nano-structure, Al₂O₃ layer, and TiNₓO_{y} layer are the same ˜2 nm. More than 100 consecutive switching cycles have measured. A larger memory window of Ir nano-structure interfacial layer has observed. A read voltage is 0.2 V. Good switching uniformity is also observed for the Ir nanostructure devices. This I-RRAM device shows low current operation of 10 nA and low voltage of±1.5 V. To sum up, the present discloses a memory structure in detail. With the iridium oxide film, the number of the metal particles in the electrodes diffusing to the dielectric layer in ion form or the number of oxygen vacancies in the memory can be controlled. Thereby, the operating voltage of an RRAM or a CBRAM can be lowered. The memory structure is undoubtedly a memory highly worth developing.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A memory structure, comprising:
a bottom electrode;
a dielectric layer, disposed on said bottom electrode;
an iridium oxide film, disposed on said dielectric layer; and
a top electrode, disposed on said iridium oxide film;
wherein said iridium oxide film is formed by stacking a plurality of porous iridium oxide nano-structures and a thickness of said iridium oxide film is 2 nanometers.

2. The memory structure of claim 1, wherein a material of said top electrode is selected from a group consisting of copper and silver.

3. (canceled)

4. The memory structure of claim 1, wherein said iridium oxide film comprises a plurality of vacancy parts.

5. The memory structure of claim 1, wherein a material of said top electrode is selected from a group consisting of tungsten, platinum, titanium nitride, and graphene.

6. The memory structure of claim 1, wherein a material of said dielectric layer includes silicon oxide, aluminum oxide, tantalum oxide, hafnium oxide, zirconium oxide or gadolinium oxide.

7. (canceled)
